(19) United States
(12) Patent Application Publication
(10) Pub. No.: US 2013/0200524 A1
(43) Pub. Date: Aug. 8, 2013

(54) PACKAGE-ON-PACKAGE TYPE SEMICONDUCTOR PACKAGES AND METHODS FOR FABRICATING THE SAME

(71) Applicant: Samsung Electronics Co., Ltd., Suwon-si (KR)

(72) Inventors: Seungchan Han, Cheonan-si (KR); Hyun-Cheol Kim, Asan-si (KR)

(73) Assignee: SAMSUNG ELECTRONICS CO., LTD., Suwon-si (KR)

(21) Appl. No.: 13/660,584

(22) Filed: Oct. 25, 2012

(30) Foreign Application Priority Data
Feb. 3, 2012 (KR) 10-2012-0011249

(51) Int. Cl. H01L 23/48

(52) U.S. Cl. 257/774; 257/E23.01

(57) ABSTRACT

A method of forming a semiconductor package may include providing a first package including a first semiconductor chip mounted on a first package substrate having a via-hole and molded by a first mold layer, providing a second package including a second semiconductor chip mounted on a second package substrate having a connection pad and molded by a second mold layer, stacking the first package on the second package to vertically align the via-hole with the connection pad, forming a through-hole penetrating the first and second packages and exposing the connection pad, and forming an electrical connection part in the through-hole. The electrical connection part may electrically connect the first package and the second package to each other.

### CROSS-REFERENCE TO RELATED APPLICATIONS

This U.S. non-provisional patent application claims priority under 35 U.S.C. §119 to Korean Patent Application No. 10-2012-0011249, filed on Feb. 3, 2012, the entirety of which is incorporated by reference herein.

### BACKGROUND

Inventive concepts relate to a semiconductor and, more particularly, to semiconductor packages and methods of fabricating the same.

One constant in the world of electronics is the demand for increased functional density: greater circuit capacity packed within ever-smaller volumes. One approach to achieving such miniaturization is a packaging technique referred to as “package-on-package,” which unites a plurality of semiconductor packages as one. As the capacities of the united packages increase, the interconnection requirements may increase and, in order to satisfy the need for greater interconnection capacity without increasing the volume of the package-on-package, individual interconnections are reduced in size.

In package-on-package structures top and bottom packages may be interconnected by solder balls to form a ball-grid-array (BGA) type semiconductor package. At high temperatures, one, or both, of the joined packages may warp, thereby jeopardizing solder joint reliability and the reliability of the stacked semiconductor devices. Additionally, the height (and overall volume) of the stacked package may be increased.

### SUMMARY

Exemplary embodiments in accordance with principles of inventive concepts may provide package-on-package (POP) type semiconductor devices having improved mechanical durability and methods of fabricating the same.

Exemplary embodiments in accordance with principles of inventive concepts may also provide POP type semiconductor devices capable of securing reliability of an electrical characteristic and methods of fabricating the same. A semiconductor package is thereby provided that improves reliability and decreases volume.

Some features of inventive concepts may be that electrical connection part penetrating lower and upper packages may be formed to improve bonding strength and/or electrical connection reliability of the lower and upper packages. Other features of inventive concepts may be that warpage phenomenon of the lower and upper packages caused by a reflow process may be minimized. Still other features of inventive concepts may be that a gap between the lower and upper packages may be minimized to realize thin packages.

In one aspect of exemplary embodiments in accordance with principles of inventive concepts, a method of fabricating a semiconductor package may include: providing a first package including a first semiconductor chip mounted on a first package substrate having a via-hole, the first semiconductor molded by a first mold layer; providing a second package including a second semiconductor chip mounted on a second package substrate having a connection pad, the second semiconductor chip molded by a second mold layer; stacking the first package on the second package to vertically align the via-hole with the connection pad; forming a through-hole penetrating the first and second packages and exposing the connection pad; and forming an electrical connection part in the through-hole, the electrical connection part electrically connecting the first package and the second package to each other.

In some exemplary embodiments in accordance with principles of inventive concepts, providing the first package may include: providing the first package substrate having a via; patterning the via to form the via-hole penetrating the first package substrate; and forming the first mold layer on the first package substrate.

In other exemplary embodiments in accordance with principles of inventive concepts, the method may further include: forming an insulating layer covering an inlet of the via-hole on the first package substrate before forming the first mold layer.

In still other exemplary embodiments in accordance with principles of inventive concepts, providing the second package may include: bonding the second semiconductor chip to the second package substrate in a flip chip bonding method; and forming the second mold layer on the second package substrate, the second mold layer molding the second semiconductor chip and having a top surface substantially coplanar with a non-active surface of the second semiconductor chip.

In yet other exemplary embodiments in accordance with principles of inventive concepts, stacking the first package on the second package may include: confronting the first package substrate with the second semiconductor chip to stack the first package on the non-active surface of the second semiconductor chip.

In yet still other exemplary embodiments in accordance with principles of inventive concepts, stacking the first package on the second package further may include: providing an adhesive layer between the first package and the second package.

In yet still other exemplary embodiments in accordance with principles of inventive concepts, forming the through-hole may include: forming a first hole penetrating the first mold layer and connected to the via-hole; and forming a second hole penetrating the second mold layer and connected to the via-hole.

In yet still other exemplary embodiments in accordance with principles of inventive concepts, forming the through-hole may include: forming the first hole by a laser drilling process; and forming the second hole by the laser drilling process.

In yet still other exemplary embodiments in accordance with principles of inventive concepts, forming the electrical connection part may include: filling the second hole and the via hole with solder; and reflowing the solder.

In yet still other exemplary embodiments in accordance with principles of inventive concepts, after forming the electrical connection part, the method may further include: filling the first hole with an insulator.

In another aspect in accordance with principles of inventive concepts, a semiconductor package may include: a first package including a first semiconductor chip mounted on a first package substrate having a via and molded by a first mold layer; a second package stacked on the first package, the second package including a second semiconductor chip mounted on a second package substrate having a connection pad and partially molded by a second mold layer, and the second semiconductor chip having a top surface substantially coplanar with a top surface of the second mold layer; and an electrical connection part configured to electrically connect the first package and the second package to each other, the electrical connection part having a first end portion connected to the connection pad and a second end portion penetrating the second mold layer and the first package substrate so as to be in contact with the via.

In some exemplary embodiments in accordance with principles of inventive concepts, the first package substrate may be stacked on a top surface of the second semiconductor chip.

In other exemplary embodiments in accordance with principles of inventive concepts, the electrical connection part may completely penetrate the second mold layer and the first package substrate and partially penetrate the first mold layer.

In still other exemplary embodiments in accordance with principles of inventive concepts, the semiconductor package may further include: a through-hole including a first hole penetrating the first mold layer, a via-hole penetrating the via and connected to the first hole, and a second hole penetrating the second mold layer and connected to the via-hole. The electrical connection part may fill the second hole and the via-hole.

In yet other exemplary embodiments in accordance with principles of inventive concepts, the semiconductor package may further include: an insulator filling the first hole.

In exemplary embodiments in accordance with principles of inventive concepts, an electronic device includes a first package including a first semiconductor chip mounted on a first package substrate having a via and molded by a first mold layer; a second package stacked on the first package, the second package including a second semiconductor chip mounted on a second package substrate having a connection pad and partially molded by a second mold layer, and the second semiconductor chip having a top surface substantially coplanar with a top surface of the second mold layer, wherein one of the first and second semiconductor chips is a memory chip; and an electrical connection part configured to electrically connect the first package and the second package to each other, the electrical connection part having a first end portion connected to the connection pad and a second end portion penetrating the second mold layer and the first package substrate so as to be in contact with the via.

A solid state drive may include a memory packaged in accordance with principles of inventive concepts and a memory interface. Such a device may further include a central processing unit and may be a mobile electronic device, for example. In embodiments wherein the device is a mobile electronic device it may be one of a smart phone, a tablet computer, an MP3 player, a personal digital assistant, for example.

### BRIEF DESCRIPTION OF THE DRAWINGS

Inventive concepts will become more apparent in view of the attached drawings and accompanying detailed description.

FIGS. 1A to 1G are cross-sectional views illustrating a method of fabricating a semiconductor package according to some exemplary embodiments in accordance with the principles of inventive concepts;

FIG. 1H is a cross-sectional view illustrating a modified example of FIG. 1G;

FIGS. 2A to 2E are cross-sectional views illustrating a method of fabricating a semiconductor package according to some exemplary embodiments in accordance with the principles of inventive concepts;

FIG. 3A is a schematic block diagram illustrating an example of memory cards including semiconductor packages according to some exemplary embodiments in accordance with the principles of inventive concepts and

FIG. 3B is a schematic block diagram illustrating an example of information processing systems including semiconductor packages according to some exemplary embodiments in accordance with the principles of inventive concepts.

### DETAILED DESCRIPTION OF THE EMBODIMENTS

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”). The word “or” is used in an inclusive sense, unless otherwise indicated.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “bottom,” “below,” “lower,” or “beneath” other elements or features would then be oriented “atop,” or “above,” the other elements or features. Thus, the exemplary terms “bottom,” or “below” can encompass both an orientation of above and below, top and bottom. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In exemplary embodiments in accordance with principles of inventive concepts, semiconductor packages may be joined to form a package-on-package semiconductor device in which electrical connections penetrate the joined packages. The semiconductor packages may be electrically connected using through-holes that penetrate the packages, with a conductor, such as solder, formed in the through-holes, then reflowed. The reflow process may be carried out after the packages are bonded and, because the packages are already bonded during the reflow process, deleterious effects of the reflow process may be avoided. That is, for example, the high temperatures associated with a reflow process may tend to warp a semiconductor package, with the packages bonded, they are less likely to warp and, if they do warp, they may warp in unison, or degree to which they warp may be reduced. A method and apparatus in accordance with principles of inventive concepts will, therefore, reduce damage due to warpage of semiconductor packages and/or reduce damage to electrical interconnections in POP packages, thereby improving the reliability of semiconductor packages that combine a plurality of semiconductor packages. Additionally, because the joined packages need not be separated by solder balls, or other somewhat bulky interconnection materials, the packages may be more tightly packed and, as a result, the thickness and volume of the completed semiconductor package may be less than associated with a conventional packaging process.

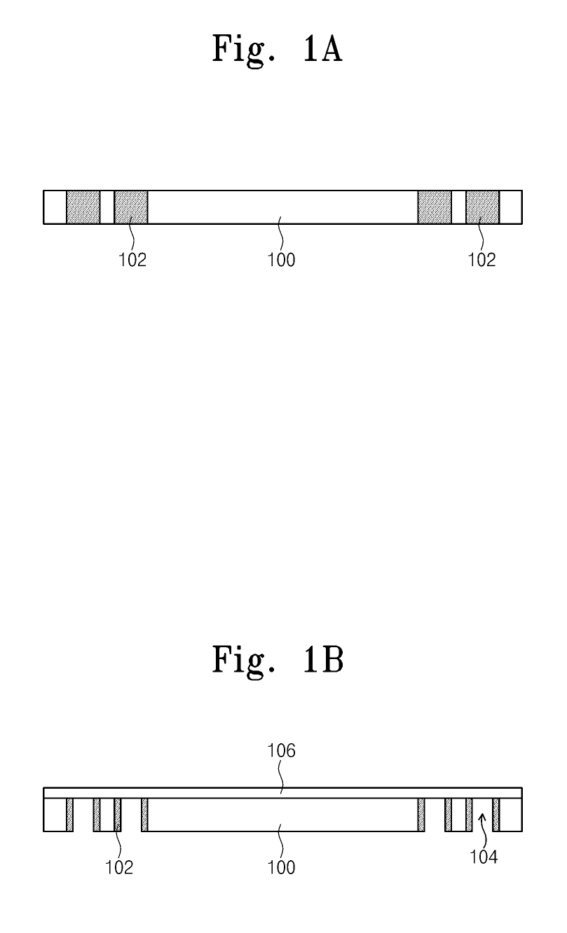

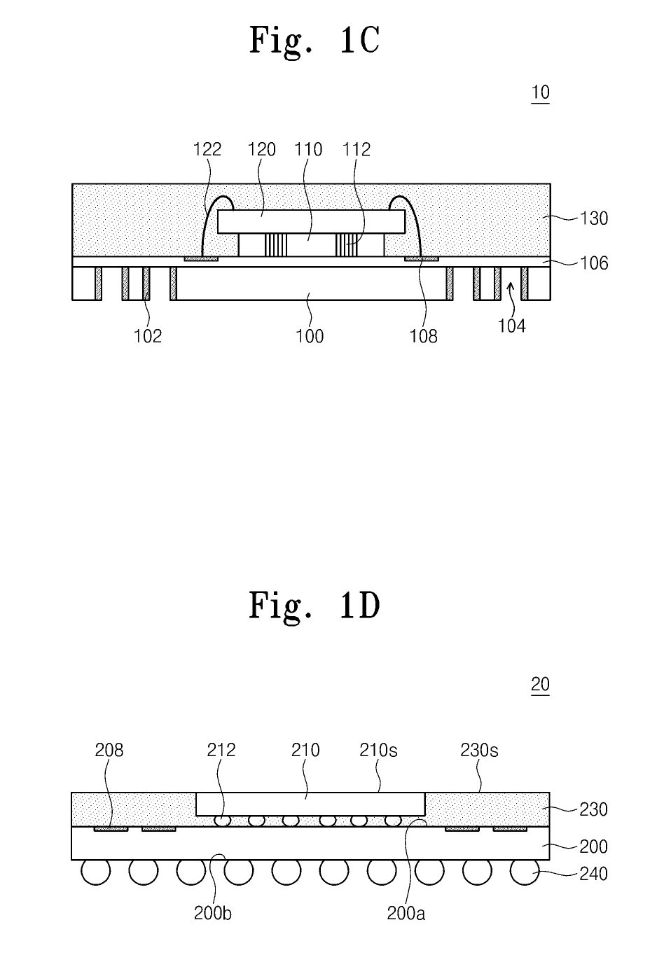

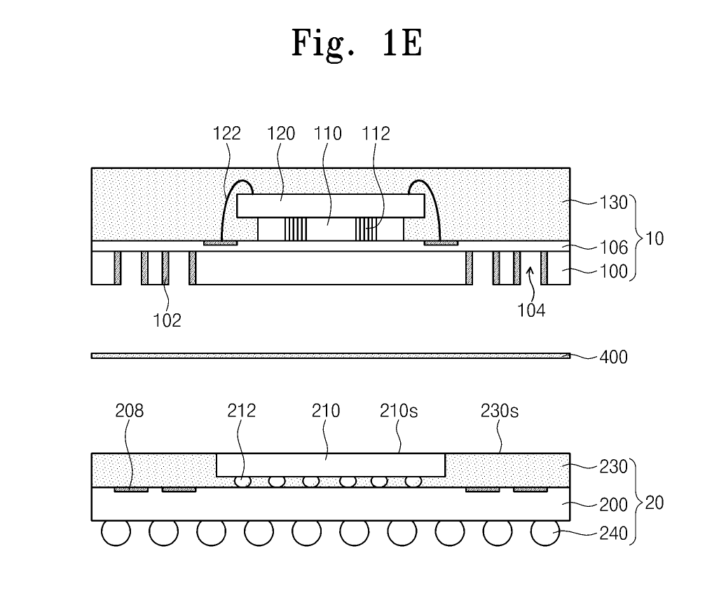

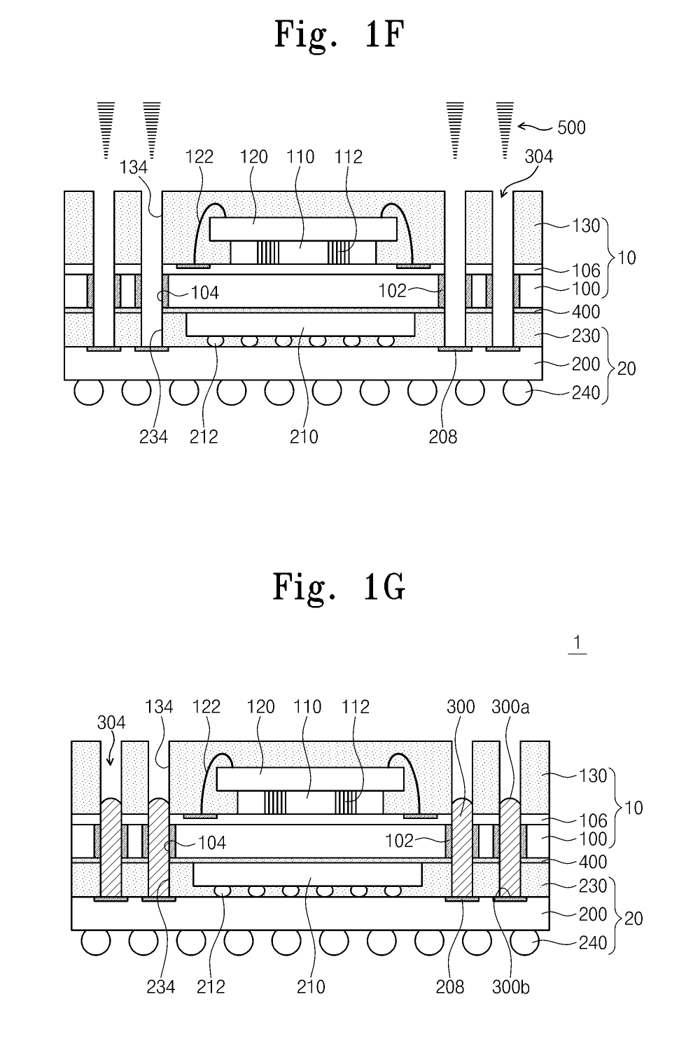

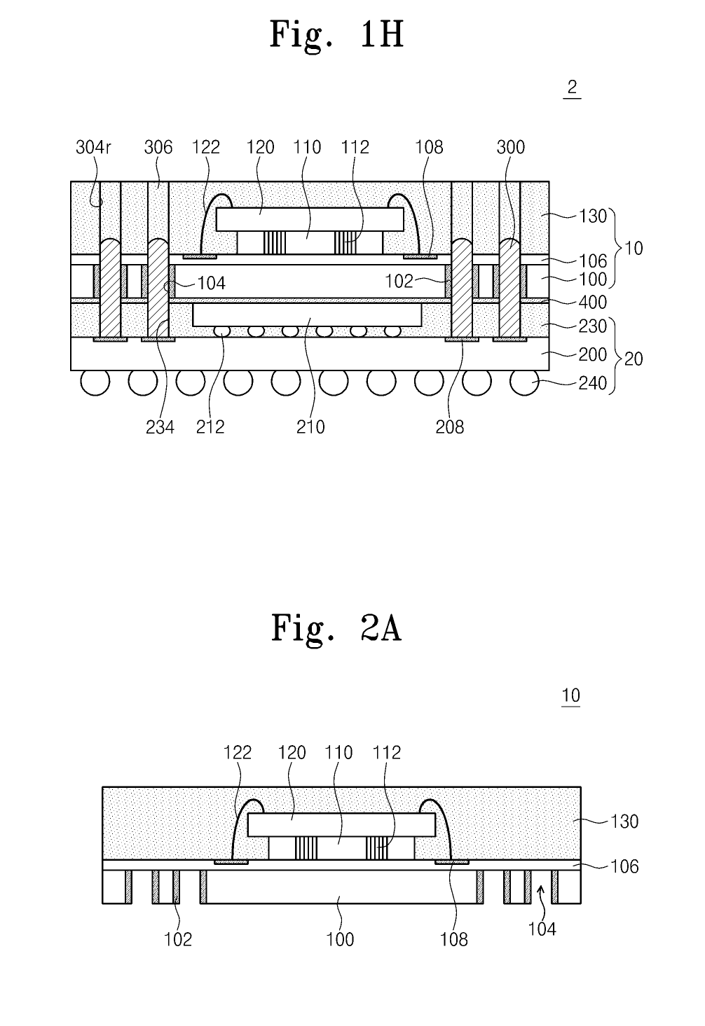

FIGS. 1A to 1G are cross-sectional views illustrating a method of fabricating a semiconductor package according to exemplary embodiments in accordance with principles of inventive concepts. FIG. 1H is a cross-sectional view illustrating a modified example of FIG. 1G.

Referring to FIG. 1A, a first package substrate 100 may include a printed circuit board provided with one or more vias 102. For example, the via 102 may include a metal layer provided to an edge of the first package substrate 100. However, exemplary embodiments in accordance with inventive concepts are not limited thereto. Each of the vias 102 may have a circular pillar-shape or a polygonal pillar-shape, for example.

Referring to FIG. 1B, via-holes 104 may be formed to penetrate the vias 102. The via-holes 104 may be formed by a mechanical drilling process or a laser drilling process, for example. When the via-holes 104 are formed, portions of the vias 102 may remain. By the formation of the via-holes 104, the vias 102 may be changed into a hollowed-out cylinder-shape, for example. As illustrated in FIG. 1C, if a first mold layer 130 is formed on the first package substrate 100, an insulating layer 106 may be formed on the first package substrate 100 to prevent an epoxy molding compound (EMC), for example, from filling the via-holes 104. The insulating layer 106 may be formed by coating a solder resist (SR), or by sticking an insulating film on the first package substrate 100, for example.

Referring to FIG. 1C, one or more first semiconductor chips 110 and 120 may be mounted on the first package substrate 100 and then a first mold layer 130 molding the first semiconductor chips 110 and 120 may be formed to form a first package 10. In other embodiments, after the first package 10 is formed without the via-holes 104, the via-holes 104 may be formed. For example, the first mold layer 130 may include epoxy molding resin (EMC). The first semiconductor chips 110 and 120 may be mounted on the insulating layer 106. The first semiconductor chips 110 and 120 may include a lower chip 110 and an upper chip 120 stacked on the lower chip 110. At least one of the lower chip 110 and the upper chip 120 may be a memory chip, for example, but inventive concepts are not limited thereto. The lower chip 110 may be electrically connected to the first package substrate 100 through one or more through-electrodes 112. The upper chip 120 may be electrically connected to the lower chip 110 and/or the first package substrate 100 through bonding wires 122 and/or through-electrodes 112. The first package substrate 100 or the insulating layer 106 may include wire-bonding pads 108 that may be electrically connected to the bonding wires 122. The first package substrate 100 or the insulating layer 106 may include through-electrode-bonding pads that may be electrically connected to the through-electrodes 112. The via-holes 104 may be provided around the first semiconductor chips 110 and 120, for example.

Referring to FIG. 1D, a second package 20 may be formed to include at least one second semiconductor chip 210 which is mounted on a second package substrate 200 and is molded by a second mold layer 230. The second package substrate 200 may include a printed circuit board (PCB), for example. The second mold layer 230 may include epoxy molding compound (EMC), also referred to herein as epoxy molding resin. The second semiconductor chip 210 may be a memory chip, for example. However, inventive concepts are not limited thereto. The second semiconductor chip 210 may be electrically connected to the second package substrate 200 through one or more solder bumps 212. The second package substrate 200 may include connection pads 208 provided around the second semiconductor chip 210. If the first package 10 is stacked on the second package 20, the connection pads 208 may be vertically aligned with the via-holes 104. The second mold layer 230 may partially mold the second semiconductor chip 210. For example, in an exemplary embodiment in accordance with principles of inventive concepts, a top surface 230s of the second mold layer 230 may be substantially coplanar with a top surface 210s of the second semiconductor chip 210. The top surface 210s of the second semiconductor chip 210 may be a non-active surface or an active surface. In an exemplary embodiment in accordance with principles of inventive concepts in which the second semiconductor chip 210 is mounted on the second package substrate 200 by a flip chip bonding method, the top surface 210s of the second semiconductor chip 210 may be a non-active surface. One or more solder balls 240 may be adhered to the second package substrate 200. The second semiconductor chip 210 may be mounted on a top surface 200a of the second package substrate 200. The solder balls 240 may be adhered to a bottom surface 200b opposite to the top surface 200a of the second package substrate 200.

Referring to FIG. 1E, the first package 10 may be stacked on the second package 20. In some exemplary embodiments in accordance with principles of inventive concepts, the top surface 210s of the second semiconductor chip 210 may be arranged with the first package substrate 100 so as to stack the first package 10 on the second package 20. In such exemplary embodiments, the via-holes 104 may be vertically aligned with the connection pads 208. A transmission vision apparatus (e.g., an X-ray apparatus) may be used to confirm whether a center axis of the via-hole 104 coincides with a center axis of the connection pad 208, and adjustments may be made to align the center axes. In exemplary embodiments in accordance with principles of inventive concepts, an adhesive layer 400 may be further provided between the first package 10 and the second package 20. In the exemplary embodiment of FIG. 1E, the adhesive layer 400 may be provided between the first package substrate 100 and the top surface 210s of the second semiconductor chip 210. The adhesive layer 400 may include a solid phase film or a liquid adhesive, for example.

In the exemplary embodiment in accordance with principles of inventive concepts of FIG. 1F, through-holes 304 may be formed to expose the connection pads 208 when the first package 10 is bonded to the second package 20. For example, the through-holes 304 may be formed to substantially vertically penetrate the first and second packages 10 and 20. Such aligned through-holes 304 may be formed by a laser drilling process using laser 500 or a mechanical drilling process, for example. In exemplary embodiments in accordance with principles of inventive concepts, each of the through-holes 304 may include a first hole 134 substantially vertically penetrating the first mold layer 130 and the insulating layer 106, a second hole 234 substantially vertically penetrating the second mold layer 230, and the via-hole 104 between the first hole 134 and the second hole 234. The through-holes 304 may have circular shapes or polygonal shapes when viewed from a top plan. In exemplary embodiments in accordance with principles of inventive concepts, the first hole 134 and the second hole 234 may be formed simultaneously by a one-step laser-drilling process, thereby yielding the through-hole 304. Alternatively, in other exemplary embodiments in accordance with principles of inventive concepts, the through-holes 304 may be formed by a multi-step laser drilling process out of consideration for factors such as materials and/or thicknesses of the first and second mold layers 130 and 230 and widths and/or depths of the through-holes 304. The first hole 134 and the second hole 234 may be sequentially formed by the multi-step laser drilling process. In some exemplary embodiments in accordance with principles of inventive concepts, after the through-holes 304 are formed, a cleaning process may be performed to remove by-products and/or contaminations that may be produced during the drilling process.

In the exemplary embodiment in accordance with principles of inventive concepts of FIG. 1G, the through-holes 304 may be filled with a conductor to form connection parts 300 so as to electrically connect the first package 10 and to the second package 20. The connection parts 300 may be formed of metal (e.g., gold, silver, nickel, and/or copper) or solder. For example, the through-holes 304 may be filled with solder powder or solder paste and then a reflow process may be performed, thereby forming the connection parts 300. The connection parts 300 may fully or partially fill the through-holes 304. For example, the connection part 300 may fill at least the second hole 234 and the via-hole 104. In exemplary embodiments in accordance with principles of inventive concepts, the connection part 300 may include a bottom end 300b directly in contact with the connection pad 208 and a top end 300a extending from the bottom end 300b. The top end 300a of the connection part 300 may be directly in contact with the via 102 or extend into first hole 134 in a portion of the first mold layer 130. In other exemplary embodiments, the connection part 300 may fully fill the second hole 234, the via-hole 104, and the first hole 134. Flux may be provided into the through-holes 304 before the connection parts 300 are formed by the soldering.

A package-on-package (POP) type semiconductor package 1 may be formed through the exemplary series of processes in accordance with principles of inventive concepts described above. The semiconductor package 1 may have a fan-out or fan-in structure. The connection parts 300 may penetrate at least the second mold layer 230 and the first package substrate 100. In accordance with principles of inventive concepts, it may be possible to improve a mechanical and/or electrical joint (e.g., a solder joint) between the first package 10 and the second package 20 employing processes as just described. Additionally, the connection parts 300 may improve reliability of electrical connection between the first package 10 and the second package 20. Since the solder may be reflowed to form the connection parts 300 after the first package 10 is stacked on the second package 20, warpage of the semiconductor package 1, and attendant reduced reliability due to a reflow process may be minimized or prevented. Because the second mold layer 230 exposes the top surface 210s of the second semiconductor chip 210, the distance between the first package 10 and the second package 20 may be minimized and the total height (and volume) of the semiconductor package 1 may be minimized or reduced when compared with conventional POP structures.

In other exemplary embodiments in accordance with principles of inventive concepts, as illustrated in FIG. 1H, an upper region 304r of the through-hole 304 that is not filled with the connection part 300 may be filled with an insulator 306, for example, epoxy molding compound (EMC). In this manner, a semiconductor package 2 including the insulator 306 may be formed.

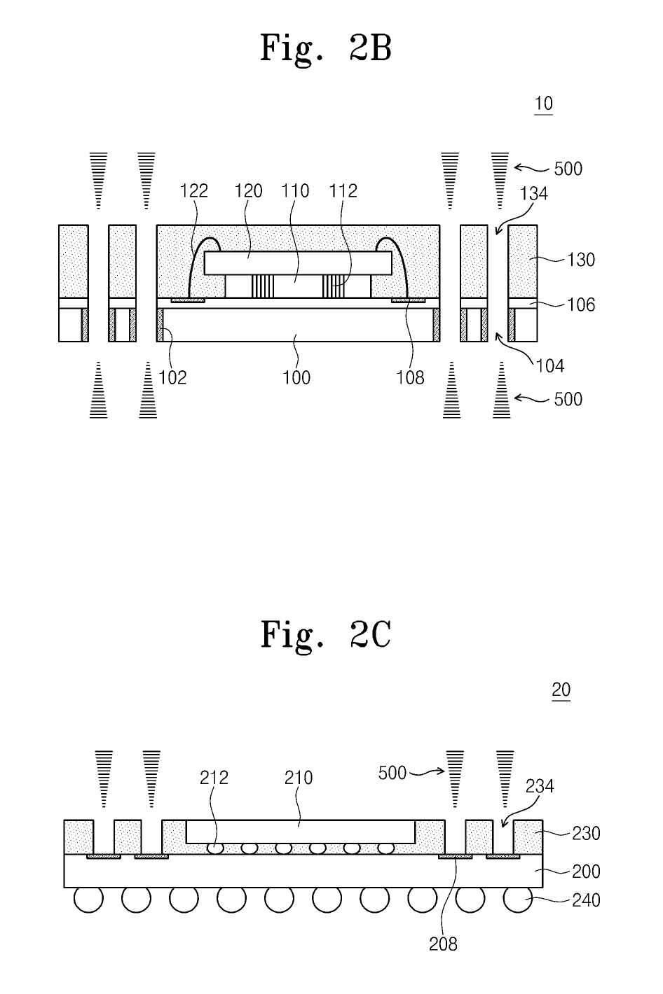

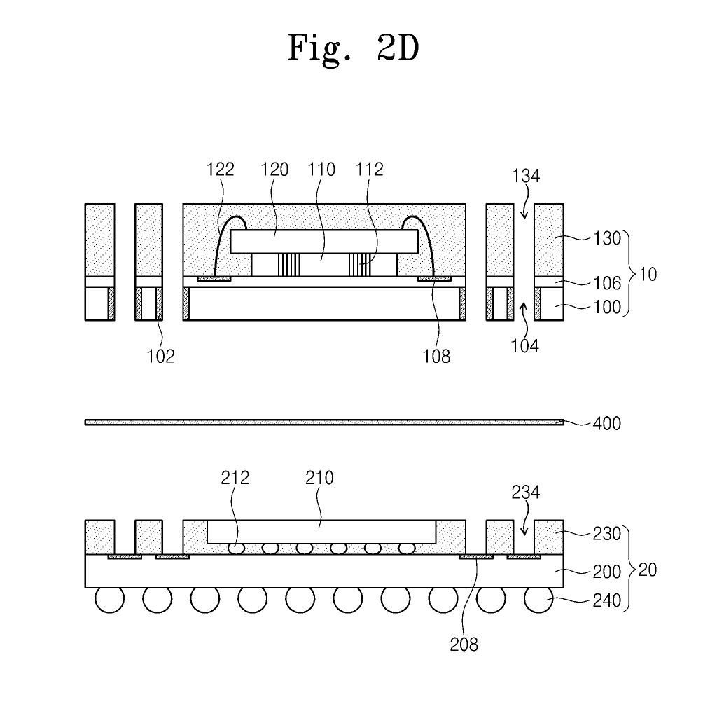

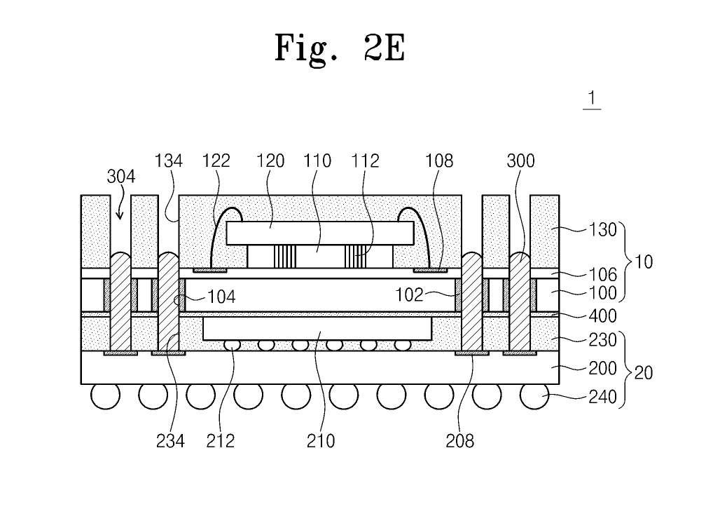

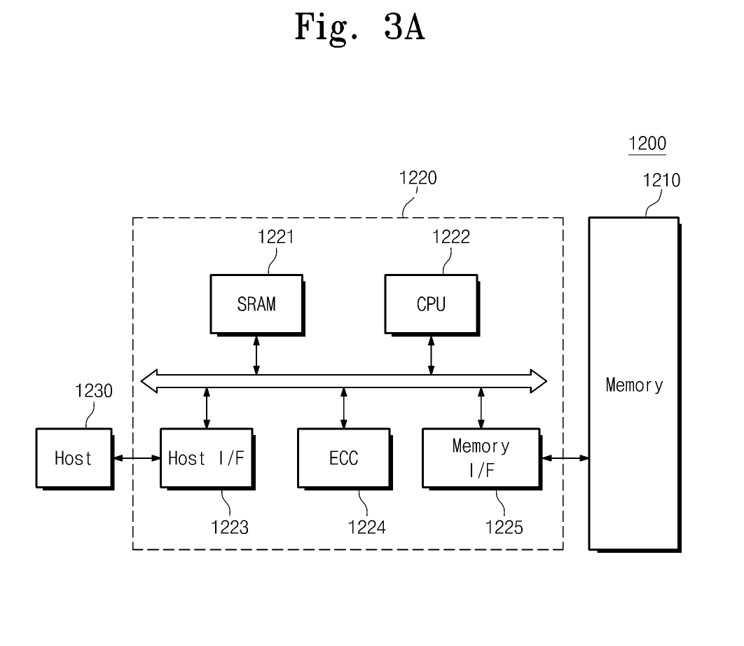

FIGS. 2A to 2E are cross-sectional views illustrating an exemplary method of fabricating a semiconductor package in accordance with principles of inventive concepts.

Referring to FIG. 2A, the first package 10 may be formed by the same processes as or similar processes to those described with reference to FIGS. 1A to 1C. For example, vias 102 provided to a first package substrate 100 may be mechanically drilled or laser-drilled to form via-holes 104. A solder resist may be coated on the first package substrate 100 or an insulating film may be adhered to the first package substrate 100 such that an insulating layer 106 may be formed to cover top-inlets of the via-holes 104. One or more first semiconductor chips 110 and 120 may be mounted on the first package substrate 100 and then a first mold layer 130 may be formed to form the first package 10. In other exemplary embodiments in accordance with principles of inventive concepts, after the first semiconductor chips 110 and 120 may be mounted on the first package substrate 100 not having the via-holes 104, the first mold layer 130 may be formed and then a laser may be irradiated from below the first package substrate 100 to form the via-holes 104, for example.

Referring to FIG. 2B, first holes 134 may be formed to penetrate the first package 10 and may be connected to the via-holes 104. The first holes 134 may be formed by a mechanical drilling process or a laser drilling process. For example, the first holes 134 may be formed by a top laser method irradiating a laser 500 toward a top of the first mold layer 130. If the first holes 134 are formed by the top laser method, a mark for confirming positions of the via-holes 104 may be further formed on the first package 10. In other exemplary embodiments in accordance with principles of inventive concepts, the first holes 134 may be formed by a bottom laser method irradiating the laser 500 toward a bottom of the first package substrate 100. If the first holes 134 are formed by the bottom laser method, positions of the via-holes 104 may be easily confirmed because the via-holes 104 are exposed. In some exemplary embodiments in accordance with principles of inventive concepts, after the first holes 134 are formed, a cleaning process may be performed to remove by-products and/or contaminants produced during the drilling process.

Referring to FIG. 2C, a second package 20 may be provided. The second package 20 may include a second semiconductor chip 210 that is mounted on a second package substrate 200. The second semiconductor chip 210 may be molded by a second mold layer 230. Second holes 234 may be formed to penetrate the second mold layer 230. The second holes 234 may expose connection pads 208. The second holes 234 may be formed by a laser drilling process using a laser 500 irradiated toward a top of the second mold layer 230. Additionally, after the second holes 234 are formed, a cleaning process may be performed to remove by-products and/or contaminants produced during the drilling process.

Referring to FIG. 2D, the first package 10 may be stacked on the second package 20. For example, the second semiconductor chip 210 may be joined with the first package substrate 100 so as to stack the first package 10 on the second package 20. In such an exemplary embodiment, the via-holes 104 may be vertically aligned with the second holes 234 and the vertical alignment may be confirmed by a transmission vision apparatus (e.g., an X-ray apparatus), for example. In exemplary embodiments, an adhesive layer 400, such as a solid phase film or a liquid adhesive, may be provided between the first package 10 and the second package 20.

Referring to FIG. 2E, through-holes 304 may be filled with a conductor to form connection parts 300 electrically connecting the first package 10 and the second package 20 to each other. Each of the through-holes 304 may include the first hole 134, the via-hole 104, and the second hole 234 that are vertically aligned with each other. The connection parts 300 may be formed of metal (e.g., gold, silver, nickel, and/or copper) or solder. In exemplary embodiments in accordance with principles of inventive concepts, the through-holes 304 may be filled with solder powder or solder paste and then a reflow process may be performed, thereby forming the connection parts 300. The connection parts 300 may fully or partially fill the through-holes 304. For example, the connection part 300 may fill at least the second hole 234 and the via-hole 104, so that the connection part 300 may be directly in contact with the connection pad 208 and the via 102. A POP type semiconductor package 1 having a fan-out structure may be formed through the series of the processes described above.

In other embodiments, the semiconductor package 1 may be formed to have a fan-in structure. In still other embodiments, the semiconductor package 1 may further include an insulator (e.g., epoxy molding resin (EMC)) filling an upper region of the through-hole 304 not filled with the connection part 300 as described with reference to FIG. 1H.

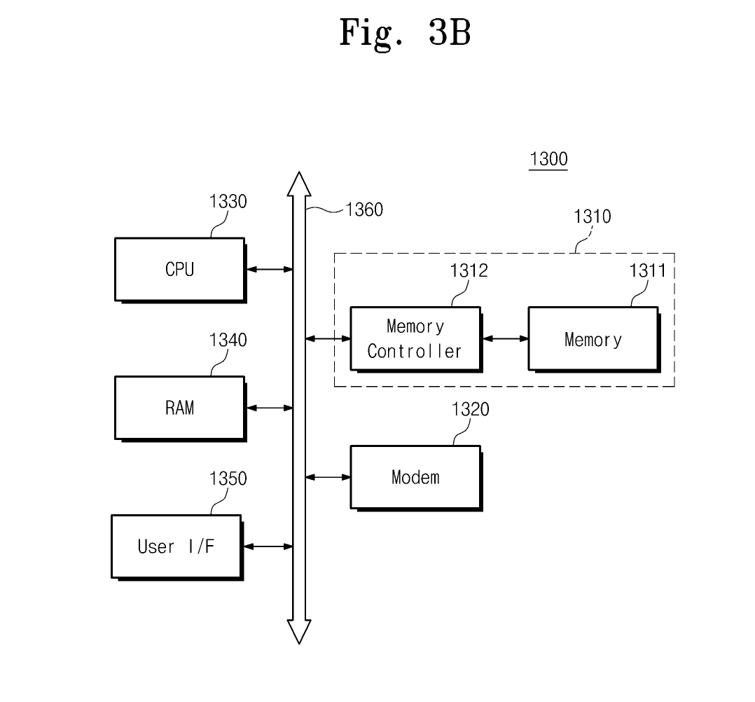

FIG. 3A is a schematic block diagram illustrating an example of memory cards including semiconductor packages in accordance with principles of inventive concepts. FIG. 3B is a schematic block diagram illustrating an example of information processing systems including semiconductor packages in accordance with principles of inventive concepts.

Referring to FIG. 3A, a memory card 120 may include a memory controller 1220 that controls data communication between a host and the memory device 1210. An SRAM device 1221 may be used as an operation memory of a central processing unit (CPU) 1222. A host interface unit 1223 may be configured to include a data communication protocol between the memory card 1200 and the host. An error check and correction (ECC) block 1224 may detect and correct errors of data which are read out from the memory device 1210. A memory interface unit 1225 may interface with the memory device 1210. The CPU 1222 may perform overall operations for data exchange of the memory controller 1220. A device, such as the memory device 1210 may include a semiconductor package in accordance with principles of inventive concepts, such as packages 1 and 2, previously described. Memory card 120 may be employed by a solid state disk (SSD) or a mobile electronic device such as a smart phone, a tablet computer, an MP3 player, or a personal digital assistant, for example.

Referring to FIG. 3B, an information processing system 1300 may include a memory system 1310 provided with a device in accordance with principles of inventive concepts, such as one employing semiconductor package 1 or 2, previously described. The information process system 1300 may include a mobile device or a computer. For example, the information system 1300 may include the memory system 1310, a modem 1320, a central processing unit (CPU) 1330, a RAM 1340, a user interface unit 1350. The memory system 1310 may include a memory device 1311 and a memory controller 1312. The memory system 1310 may consist of the same elements as the memory card 1200 of FIG. 3A, for example. The memory system 1310 may store data processed by the CPU 1330 or data inputted from an external system. The information processing system 1300 may further include a memory card, a solid state disk (SSD), and/or other application chipsets.

According to embodiments of inventive concepts, since the electrical connection is formed to penetrate lower and upper packages, a mechanical durability between the lower and upper packages may be improved, and reliability of electrical connection between the lower and upper packages may be secured. Additionally, since the electrical connection part is formed after the lower and upper packages are bonded to each other, the warpage of the lower and upper packages that may be caused by a reflow process may be minimized. Furthermore, a gap between the lower and upper packages may be minimized to realize thin packages.

That is, in exemplary embodiments in accordance with principles of inventive concepts, semiconductor packages may be joined to form a package-on-package semiconductor device in which electrical connections penetrate the joined packages. The semiconductor packages may be electrically connected using through-holes that penetrate the packages, with a conductor, such as solder, formed in the through-holes, then reflowed. The reflow process may be carried out after the packages are bonded and, because the packages are already bonded during the reflow process, deleterious effects of the reflow process may be avoided. That is, for example, the high temperatures associated with a reflow process may tend to warp a semiconductor package, with the packages bonded, they are less likely to warp and, if they do warp, they may warp in unison, or degree to which they warp may be reduced. A method and apparatus in accordance with principles of inventive concepts will, therefore, reduce damage due to warpage of semiconductor packages and/or reduce damage to electrical interconnections in POP packages, thereby improving the reliability of semiconductor packages that combine a plurality of semiconductor packages. Additionally, because the joined packages need not be separated by solder balls, or other somewhat bulky interconnection materials, the packages may be more tightly packed and, as a result, the thickness and volume of the completed semiconductor package may be less than associated with a conventional packaging process.

While the inventive concepts have been described with reference to exemplary embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

1-10. (canceled)

11. A semiconductor package comprising:
a first package including a first semiconductor chip mounted on a first package substrate having a via and molded by a first mold layer;
a second package stacked on the first package, the second package including a second semiconductor chip mounted on a second package substrate having a connection pad and partially molded by a second mold layer, and the second semiconductor chip having a top surface substantially coplanar with a top surface of the second mold layer; and
an electrical connection part configured to electrically connect the first package and the second package to each other, the electrical connection part having a first end portion connected to the connection pad and a second end portion penetrating the second mold layer and the first package substrate so as to be in contact with the via.

12. The semiconductor package of claim 11, wherein the first package substrate is stacked on a top surface of the second semiconductor chip.

13. The semiconductor package of claim 11, wherein the electrical connection part completely penetrates the second mold layer and the first package substrate and partially penetrates the first mold layer.

14. The semiconductor package of claim 11, further comprising:
a through-hole including a first hole penetrating the first mold layer, a via-hole penetrating the via and connected to the first hole, and a second hole penetrating the second mold layer and connected to the via-hole,
wherein the electrical connection part fills the second hole and the via-hole.

15. The semiconductor package of claim 14, further comprising:
an insulator filling the first hole.

16. An electronic device, comprising:
a first package including a first semiconductor chip mounted on a first package substrate having a via and molded by a first mold layer;
a second package stacked on the first package, the second package including a second semiconductor chip mounted on a second package substrate having a connection pad and partially molded by a second mold layer, and the second semiconductor chip having a top surface substantially coplanar with a top surface of the second mold layer, wherein one of the first and second semiconductor chips is a memory chip; and
an electrical connection part configured to electrically connect the first package and the second package to each other, the electrical connection part having a first end portion connected to the connection pad and a second end portion penetrating the second mold layer and the first package substrate so as to be in contact with the via.

17. A solid state drive (SSD), comprising:
an electronic device of claim 16; and
a memory interface unit to interface the at least one memory chip.

18. The SSD of claim 17, further comprising a central processing unit.

19. The SSD of claim 18, wherein the device is a mobile electronic device.

20. The SSD of claim 19, wherein the mobile device is one of: a smart phone, a tablet computer, an MP3 player, a personal digital assistant.
